(19) United States
(12) Patent Application Publication
(10) Pub. No.: US 2026/0327853 A1
(43) Pub. Date: Oct. 22, 2026

(54) COMPOSITIONS COMPRISING GALLIUM OXIDE DOPED WITH CARBON, AND METHODS OF MAKING AND USE THEREOF

(71) Applicant: Ohio State Innovation Foundation, Columbus, OH (US)

(72) Inventors: Hongping ZHAO, Dublin, OH (US); A F M Anhar Uddin BHUIYAN, Columbus, OH (US); Lingyu MENG, Columbus, OH (US)

(21) Appl. No.: 18/881,024

(22) PCT Filed: May 5, 2023
(86) PCT No.: PCT/US23/21108

§ 371 Date: Jan. 3, 2025

Related U.S. Application Data
(60) Provisional application No. 63/358,634, filed on Jul. 6, 2022.

(51) Int. Cl. C30B 29/16; C01G 15/00; C30B 25/02; H10D 62/80

(52) U.S. Cl. CPC C30B 29/16; C01G 15/00; C30B 25/02; H10D 62/875; C01P 2002/52; C01P 2006/40

(57) ABSTRACT

Disclosed herein are compositions comprising gallium oxide doped with carbon, and methods of making and use thereof. In some examples, the methods comprise contacting a first precursor and a second precursor at a first temperature, wherein the first precursor comprises carbon and gallium, and the second precursor comprises oxygen, to thereby react the first precursor and the second precursor to form the composition comprising β-Ga₂O₃ doped with carbon. In some examples, the method further comprises controlling the flow rate of the first precursor, the temperature, or a combination thereof to thereby control the concentration of carbon in the resulting composition.

### CROSS-REFERENCE TO RELATED APPLICATIONS

This application claims benefit of priority to U.S. Provisional Application No. 63/358,634 filed Jul. 6, 2022, which is hereby incorporated herein by reference in its entirety.

### STATEMENT OF GOVERNMENT SUPPORT

This invention was made with government support under grant/contract number FA9950-18-1-0479 awarded by the Air Force Office of Scientific Research, grant number 2231026 awarded by the National Science Foundation, and grant number 2019753 awarded by the National Science Foundation. The government has certain rights in the invention.

### BACKGROUND

Beta-gallium oxide (β-Ga₂O₃), with its ultrawide band gap energy (~4.8 eV), high predicted breakdown field strength (6-8 MV/cm), controllable n-type doping and availability of large area, high quality melt-grown native substrates, has spurred substantial interest for applications in high power/high frequency electronics and ultraviolet optoelectronics. One important aspect in many device designs is to introduce a charge compensation or current blocking layer (CBL) in the desired device region. In the absence of effective p-type doping in β-Ga₂O₃, an alternative route is to employ semi-insulating layer to engineer the electric field in power devices and also to suppress the substrate/epilayer interface charges. Controllable acceptor doping with lower diffusion of dopants is needed to produce high quality semi-insulating regions of devices for compensating interface charges and to create current blocking layers. The compositions, methods, and devices discussed herein addresses these and other needs.

### SUMMARY

In accordance with the purposes of the disclosed compositions, methods, and devices as embodied and broadly described herein, the disclosed subject matter relates to compositions and devices and methods of making and use thereof. For example, disclosed herein are compositions comprising gallium oxide doped with carbon, and methods of making and use thereof.

Disclosed herein are compositions comprising β-Ga₂O₃ doped with carbon, wherein the composition is semi-insulating or insulating. In some examples, the composition is further doped with hydrogen and/or silicon. In some examples, the carbon is present in the composition at a concentration of from 1×10¹⁶ per cubic centimeter to 1×10²² cm⁻³. In some examples, the composition is further doped with hydrogen and the hydrogen is present in the composition at a concentration of from 1×10¹⁶ per cubic centimeter to 1×10²² cm⁻³. In some examples, the composition is further doped with silicon and the silicon is present in the composition at a concentration of from 1×10¹⁵ per cubic centimeter to 1×10²² cm⁻³. In some examples, the concentration of carbon in the composition is greater than the concentration of hydrogen and/or silicon. In some examples, the composition has a carrier concentration of from 1×10¹⁵ per cubic centimeter to 1×10²² cm⁻³. In some examples, the composition consists essentially of β-Ga₂O₃, carbon, hydrogen, and silicon.

Also disclosed herein are methods of making any of the compositions disclosed herein. In some examples, the methods comprise contacting a first precursor and a second precursor at a first temperature, wherein the first precursor comprises carbon and gallium, and the second precursor comprises oxygen, to thereby react the first precursor and the second precursor to form the composition comprising β-Ga₂O₃ doped with carbon. In some examples, the method comprises metal organic chemical vapor deposition (MOCVD), molecular-beam epitaxy (MBE), hydride vapor phase epitaxy (HVPE), pulsed laser deposition (PLD), low pressure chemical vapor deposition (LPCVD), mist-CVD, or a combination thereof. In some examples, the method comprises metal organic chemical vapor deposition (MOCVD).

In some examples, the first precursor and/or the second precursor independently comprise(s) a fluid, such as a gas. In some examples, the first precursor further comprises hydrogen, and wherein the composition optionally further comprises hydrogen. In some examples, the first precursor comprises trimethylgallium (TMGa), triethylgallium (TEGa), Ga(DPM)₃ (DPM=dipivaloylmethanate), or a combination thereof. In some examples, the first precursor comprises trimethylgallium (TMGa). In some examples, the first precursor is provided at a flow rate of from 1 to 250 μmole/minute, from 25 to 125 μmole/minute, or from 39 to 116 μmole/minute. In some examples, the second precursor comprises O₂.

In some examples, the first temperature is from 550 °C to 1200 °C, from 550 °C to 1000 °C, or from 700 °C to 950 °C.

In some examples, the method further comprises controlling the flow rate of the first precursor, the temperature, or a combination thereof to thereby control the concentration of carbon in the resulting composition.

In some examples, the method produces the composition at a growth rate of from 0.2 to 20 μm/hour, from 1 to 10 μm/hour, from 2 to 6.75 μm/hour, or from 2 to 3.25 μm/hour.

In some examples, the method is conducted at a pressure of from 1 to 200 torr, or from 5 to 60 torr.

In some examples, the method further comprises introducing a third precursor comprising an additional dopant, such that the composition further comprises the additional dopant. In some examples, the third precursor is provided as a fluid, such as a gas. In some examples, the third precursor comprises silane (SiH₄), germane (GeH₄), disilane(Si₂H₆), bis(cyclopentadienyl)magnesium (Cp₂Mg), bis(methylcyclopentadienyl)magnesium ((MeCp)₂Mg), or a combination thereof. In some examples, the third precursor comprises silane (SiH₄).

In some examples, the first precursor, the second precursor, the third precursor (when present), or a combination thereof are independently provided with a carrier gas. In some examples, the carrier gas comprises argon, helium, N2, and the like, or combinations thereof.

Also disclosed herein are compositions made by any of the methods disclosed herein.

Also disclosed herein are devices comprising any of the compositions disclosed herein. In some examples, the device comprises a MESFET device, a MODFET device, a MOSFET device, a Current Aperture Vertical Electron Transistor (CAVET) device, or a combination thereof. In some examples, the device comprises a vertical power device. In some examples, the device comprises an optical device, an electronic device, an optoelectronic device, or a combination thereof. In some examples, the device comprises a diode.

Also disclosed herein are methods of use of any of the compositions disclosed herein.

Additional advantages of the disclosed compositions, devices, and methods will be set forth in part in the description which follows, and in part will be obvious from the description. The advantages of the disclosed compositions, devices, and methods will be realized and attained by means of the elements and combinations particularly pointed out in the appended claims. It is to be understood that both the foregoing general description and the following detailed description are exemplary and explanatory only and are not restrictive of the disclosed devices and methods, as claimed.

The details of one or more embodiments of the invention are set forth in the accompanying drawings and the description below. Other features, objects, and advantages of the invention will be apparent from the description and drawings, and from the claims.

### BRIEF DESCRIPTION OF THE FIGURES

The accompanying figures, which are incorporated in and constitute a part of this specification, illustrate several aspects of the disclosure, and together with the description, serve to explain the principles of the disclosure.

FIG. 1A. Schematic of the β-Ga₂O₃ sample layer stack grown with different TMGa flow rates.

FIG. 1B. SIMS profile of the sample shown in FIG. 1A.

FIG. 2. Carrier concentration of β-Ga₂O₃ layer grown by TMGa as a function of silane molar flow rates for different TMGa flow rates.

FIG. 3A. Schematic of the sample layer stack of TMGa grown β-Ga₂O₃ sample for different growth temperatures.

FIG. 3B. SIMS profile of the sample shown in FIG. 3A.

FIG. 4. C, H and Si incorporation as a function of growth temperature. The TMGa and silane molar flow rates were 58 μmole/min and 0.416 nmol/min, respectively.

FIG. 5. Epitaxial/Device structure of β-Ga₂O₃ based MESFETs grown using semi insulating TMGa-grown β-Ga₂O₃ (C-containing) buffer layer to suppress the substrate-interface charge.

FIG. 6. Epitaxial/Device structure of β-(AlₓGa₁₋ₓ)₂O₃ based MESFETs grown using semi insulating TMGa-grown β-Ga₂O₃ buffer layer (C-containing).

FIG. 7. Schematic of a cross sectional view of an epitaxial stack of β-Ga₂O₃/(AlₓGa₁₋ₓ)₂O₃ MODFET structure grown using semi insulating TMGa-grown β-Ga₂O₃ (C-containing) buffer layer.

FIG. 8. Schematic of a cross sectional view of a generic current aperture vertical Ga₂O₃ MOSFET grown using semi-insulating TMGa-grown β-Ga₂O₃ (C-containing) current blocking layer (CBL).

FIG. 9A. Schematic of the SIMS sample with stacked sub-layers grown with different TMGa molar flow rate/growth rate (GR=growth rate). The growth temperature and chamber pressure were kept at 950 °C and 60 torr, respectively. The silane molar flow rate was set at 0.416 nmol/min for the Si-doped sub-layers.

FIG. 9B. The SIMS depth profiles of [C], [H], and [Si] of the sample shown in FIG. 9A.

FIG. 10. The extracted C, H and Si incorporation concentration as a function of the TMGa molar flow rate from the SIMS measurement of the sample as shown in FIG. 9A-FIG. 9B.

FIG. 11A. Measured free electron carrier concentration as a function of the silane molar flow rate for three different sets of samples varying the TMGa molar flow rate/growth rate. The dashed lines indicate the net compensation levels ([C]−[H]) for the three sets of samples grown at different growth rate.

FIG. 11B. Room temperature electron mobility as a function of carrier concentration for the three sets of samples grown with different TMGa molar flow rate/growth rate. The growth temperature and chamber pressure were kept at 950 °C and 60 torr, respectively.

FIG. 12A. Schematic of the SIMS sample with stacked sub-layers grown with different temperature from 700-950 °C. The TMGa molar flow rate and chamber pressure were kept at 58 μmol/min and 60 torr, respectively. The silane molar flow rate was set at 0.416 nmol/min for the Si-doped sub-layers.

FIG. 12B. The SIMS depth profiles of [C], [H], and [Si] of the sample shown in FIG. 12A.

FIG. 13. The extracted C, H and Si incorporation concentration as a function of the growth temperature from the SIMS measurement of the sample as shown in FIG. 12A-FIG. 12B.

### DETAILED DESCRIPTION

The compositions, methods, and devices described herein may be understood more readily by reference to the following detailed description of specific aspects of the disclosed subject matter and the Examples included therein.

Before the present compositions, methods, and devices are disclosed and described, it is to be understood that the aspects described below are not limited to specific synthetic methods or specific reagents, as such may, of course, vary. It is also to be understood that the terminology used herein is for the purpose of describing particular aspects only and is not intended to be limiting.

Also, throughout this specification, various publications are referenced. The disclosures of these publications in their entireties are hereby incorporated by reference into this application in order to more fully describe the state of the art to which the disclosed matter pertains. The references disclosed are also individually and specifically incorporated by reference herein for the material contained in them that is discussed in the sentence in which the reference is relied upon.

In this specification and in the claims that follow, reference will be made to a number of terms, which shall be defined to have the following meanings.

Throughout the description and claims of this specification the word “comprise” and other forms of the word, such as “comprising” and “comprises,” means including but not limited to, and is not intended to exclude, for example, other additives, components, integers, or steps.

As used in the description and the appended claims, the singular forms “a,” “an,” and “the” include plural referents unless the context clearly dictates otherwise. Thus, for example, reference to “a composition” includes mixtures of two or more such compositions, reference to “an agent” includes mixtures of two or more such agents, reference to “the component” includes mixtures of two or more such components, and the like.

“Optional” or “optionally” means that the subsequently described event or circumstance can or cannot occur, and that the description includes instances where the event or circumstance occurs and instances where it does not.

Ranges can be expressed herein as from “about” one particular value, and/or to “about” another particular value. By “about” is meant within 5% of the value, e.g., within 4, 3, 2, or 1% of the value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Values can be expressed herein as an “average” value. “Average” generally refers to the statistical mean value.

By “substantially” is meant within 5%, e.g., within 4%, 3%, 2%, or 1%.

“Exemplary” means “an example of” and is not intended to convey an indication of a preferred or ideal embodiment. “Such as” is not used in a restrictive sense, but for explanatory purposes.

It is understood that throughout this specification the identifiers “first” and “second” are used solely to aid in distinguishing the various components and steps of the disclosed subject matter. The identifiers “first” and “second” are not intended to imply any particular order, amount, preference, or importance to the components or steps modified by these terms.

References in the specification and concluding claims to parts by weight of a particular element or component in a composition denotes the weight relationship between the element or component and any other elements or components in the composition or article for which a part by weight is expressed. Thus, in a compound containing 2 parts by weight of component X and 5 parts by weight component Y, X and Y are present at a weight ratio of 2:5, and are present in such ratio regardless of whether additional components are contained in the compound.

A weight percent (wt. %) of a component, unless specifically stated to the contrary, is based on the total weight of the formulation or composition in which the component is included.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB, Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

Disclosed herein are compositions comprising β-Ga₂O₃ doped with carbon. In some examples, the composition is semi-insulating or insulating.

In some examples, the carbon is present in the composition at a concentration of 1×10¹⁶ per cubic centimeter (cm⁻³) or more (e.g., 5×10¹⁵ cm⁻³ or more, 1×10¹⁷ cm⁻³ or more, 5×10¹⁷ cm⁻³ or more, 1×10¹⁸ cm⁻³ or more, 5×10¹⁸ cm⁻³ or more, 1×10¹⁹ cm⁻³ or more, 5×10¹⁹ cm⁻³ or more, 1×10²⁰ cm⁻³ or more, 5×10²⁰ cm⁻³ or more, 1×10²¹ cm⁻³ or more, or 5×10²¹ cm⁻³ or more). In some examples, the carbon is present in the composition at a concentration of 1×10²² cm⁻³ or less (e.g., 5×10²¹ cm⁻³ or less, 1×10²¹ cm⁻³ or less, 5×10²⁰ cm⁻³ or less, 1×10²⁰ cm⁻³ or less, 5×10¹⁹ cm⁻³ or less, 1×10¹⁹ cm⁻³ or less, 5×10¹⁸ cm⁻³ or less, 1×10¹⁸ cm⁻³ or less, 5×10¹⁷ cm⁻³ or less, 1×10¹⁷ cm⁻³ or less, or 5×10¹⁶ cm⁻³ or less). The concentration of carbon in the composition can range from any of the minimum values described above to any of the maximum values described above. For example, the carbon can be present in the composition at a concentration of from 1×10¹⁶ per cubic centimeter to 1×10²² cm⁻³ (e.g., from 1×10¹⁶ cm⁻³ to 1×10¹⁹ cm⁻³, from 1×10¹⁹ cm⁻³ to 1×10²² cm⁻³, from 1×10¹⁶ cm⁻³ to 1×10¹⁸ cm⁻³, from 1×10¹⁸ cm⁻³ to 1×10²⁰ cm⁻³, from 1×10²⁰ cm⁻³ to 1×10²² cm⁻³, from 1×10¹⁶ cm⁻³ to 1×10²¹ cm⁻³, from 1×10¹⁶ cm⁻³ to 1×10²⁰ cm⁻³, from 1×10¹⁶ cm⁻³ to 1×10¹⁹ cm⁻³, from 5×10¹⁶ cm⁻³ to 1×10²² cm⁻³, from 1×10¹⁷ cm⁻³ to 1×10²² cm⁻³, from 1×10¹⁸ cm⁻³ to 1×10²² cm⁻³, from 1×10¹⁹ cm⁻³ to 1×10²² cm⁻³ , or from 5×10¹⁶ cm⁻³ to 5×10²¹ cm⁻³).

In some examples, the composition is further doped with one or more additional dopants, such as, for example, hydrogen, silicon, or a combination thereof. In some examples, the dopants (e.g., carbon, hydrogen, and/or silicon) do not substantially diffuse.

In some examples, the composition is further doped with hydrogen and the hydrogen is present in the composition at a concentration of 1×10¹⁶ per cubic centimeter (cm⁻³) or more (e.g., 5×10¹⁶ cm⁻³ or more, 1×10¹⁷ cm⁻³ or more, 5×10¹⁷ cm⁻³ or more, 1×10¹⁸ cm⁻³ or more, 5×10¹⁸ cm⁻³ or more, 1×10¹⁹ cm⁻³ or more, 5×10¹⁹ cm⁻³ or more, 1×10²⁰ cm⁻³ or more, 5×10²⁰ cm⁻³ or more, 1×10²¹ cm⁻³ or more, or 5×10²¹ cm⁻³ or more). In some examples, the hydrogen is present in the composition at a concentration of 1×10²² cm⁻³ or less (e.g., 5×10²¹ cm⁻³ or less, 1×10²¹ cm⁻³ or less, 5×10²⁰ cm⁻³ or less, 1×10²⁰ cm⁻³ or less, 5×10¹⁹ cm⁻³ or less, 1×10¹⁹ cm⁻³ or less, 5×10¹⁸ cm⁻³ or less, 1×10¹⁸ cm⁻³ or less, 5×10¹⁷ cm⁻³ or less, 1×10¹⁷ cm⁻³ or less, or 5×10¹⁶ cm⁻³ or less). The concentration of hydrogen in the composition can range from any of the minimum values described above to any of the maximum values described above. For example, the hydrogen can be present in the composition at a concentration of from 1×10¹⁶ per cubic centimeter to 1×10²² cm⁻³ (e.g., from 1×10¹⁶ cm⁻³ to 1×10¹⁹ cm⁻³, from 1×10¹⁹ cm⁻³ to 1×10²² cm⁻³, from 1×10¹⁶ cm⁻³ to 1×10¹⁸ cm⁻³, from 1×10¹⁸ cm⁻³ to 1×10²⁰ cm⁻³, from 1×10²⁰ cm⁻³ to 1×10²² cm⁻³, from 1×10¹⁶ cm⁻³ to 1×10²¹ cm⁻³, from 1×10¹⁶ cm⁻³ to 1×10²⁰ cm⁻³, from 1×10¹⁶ cm⁻³ to 1×10¹⁹ cm⁻³, from 5×10¹⁶ cm⁻³ to 1×10²²cm⁻³ , from 1×10¹⁷ cm⁻³ to 1×10²² cm⁻³, from 1×10¹⁸ cm⁻³ to 1×10²² cm⁻³, from 1×10¹⁹ cm⁻³ to 1×10²² cm⁻³, or from 5×10¹⁶ cm⁻³ to 5×10²¹ cm⁻³).

In some examples, the composition is further doped with silicon and the silicon is present in the composition at a concentration of 1×10¹⁵ per cubic centimeter (cm⁻³) or more (e.g., 5×10¹⁵ cm⁻³ or more, 1×10¹⁶ cm⁻³ or more, 5×10¹⁶ cm⁻³ or more, 1×10¹⁷ cm⁻³ or more, 5×10¹⁷ cm⁻³ or more, 1×10¹⁸ cm⁻³ or more, 5×10¹⁸ cm⁻³ or more, 1×10¹⁹ cm⁻³ or more, 5×10¹⁹ cm⁻³ or more, 1×10²⁰ cm⁻³ or more, 5×10²⁰ cm⁻³ or more, 1×10²¹ cm⁻³ or more, or 5×10²¹ cm⁻³ or more). In some examples, the silicon is present in the composition at a concentration of 1×10²² cm⁻³ or less (e.g., 5×10²¹ cm⁻³ or less, 1×10²¹ cm⁻³ or less, 5×10²⁰ cm⁻³ or less, 1×10²⁰ cm⁻³ or less, 5×10¹⁹ cm⁻³ or less, 1×10¹⁹ cm⁻³ or less, 5×10¹⁸ cm⁻³ or less, 1×10¹⁸ cm⁻³ or less, 5×10¹⁷ cm⁻³ or less, 1×10¹⁷ cm⁻³ or less, 5×10^{16 cm}⁻³ or less, 1×10¹⁶ cm⁻³ or less, or 5×10¹⁵ cm⁻³ or less). The concentration of silicon in the composition can range from any of the minimum values described above to any of the maximum values described above. For example, the silicon can be present in the composition at a concentration of from 1×10¹⁵ per cubic centimeter to 1×10²² cm⁻³ (e.g., from 1×10¹⁵ cm⁻³ to 1×10¹⁹ cm⁻³, from 1×10¹⁹ cm⁻³ to 1×10²² cm⁻³ , from 1×10¹⁵ cm⁻³ to 1×10¹⁸ cm⁻³, from 1×10¹⁸ cm⁻³ to 1×10²⁰ cm⁻³, from 1×10²⁰ cm⁻³ to 1×10²² cm⁻³, from 1×10¹⁵ cm⁻³ to 1×10²¹ cm⁻³, from 1×10¹⁵ cm⁻³ to 1×10²⁰ cm⁻³, from 1×10¹⁵ cm⁻³ to 1×10¹⁹ cm⁻³, from 5×10¹⁵ cm⁻³ to 1×10²² cm⁻³, 1×10¹⁶ cm⁻³ to 1×10²² cm⁻³, from 5×10¹⁶ cm⁻³ to 1×10²² cm⁻³, from 1×10¹⁷ cm⁻³ to 1×10²² cm⁻³, from 1×10¹⁸ cm⁻³ to 1×10²² cm⁻³, from 1×10¹⁹ cm⁻³ to 1×10²² cm⁻³, or from 5×10¹⁵ cm⁻³ to 5×10²¹ cm⁻³).

In some examples, the concentration of carbon in the composition is greater than the concentration of hydrogen and/or silicon.

In some examples, the composition consists essentially of β-Ga₂O₃ and carbon, and optionally hydrogen and/or silicon. In some examples, the composition consists essentially of β-Ga₂O₃, carbon, hydrogen, and silicon. In some examples, the composition consists essentially of β-Ga₂O₃ and carbon. In some examples, the composition consists of β-Ga₂O₃ and carbon.

In some examples, the composition has a carrier concentration of 1×10¹⁵ per cubic centimeter (cm⁻³) or more (e.g., 5×10¹⁵ cm⁻³ or more, 1×10¹⁶ cm⁻³ or more, 5×10¹⁶ cm⁻³ or more, 1×10^{17 cm}⁻³ or more, 5×10¹⁷ cm⁻³ or more, 1×10¹⁸ cm⁻³ or more, 5×10¹⁸ cm⁻³ or more, 1×10¹⁹ cm⁻³ or more, 5×10¹⁹ cm⁻³ or more, 1×10²⁰ cm⁻³ or more, 5×10²⁰ cm⁻³ or more, 1×10²¹ cm⁻³ or more, or 5×10²¹ cm⁻³ or more). In some examples, the composition can have a carrier concentration of 1×10²² cm⁻³ or less (e.g., 5×10²¹ cm⁻³ or less, 1×10²¹ cm⁻³ or less, 5×10²⁰ cm⁻³ or less, 1×10²⁰ cm⁻³ or less, 5×10¹⁵ cm⁻³ or less, 1×10¹⁹ cm⁻³ or less, 5×10¹⁸ cm⁻³ or less, 1×10¹⁵ cm⁻³ or less, 5×10¹⁷ cm⁻³ or less, 1×10¹⁷ cm⁻³ or less, 5×10¹⁶ cm⁻³ or less, 1×10¹⁶ cm⁻³ or less, or 5×10¹⁵ cm⁻³ or less). The carrier concentration in the composition can range from any of the minimum values described above to any of the maximum values described above. For example, the composition can have a carrier concentration of from 1×10¹⁵ per cubic centimeter to 1×10²² cm⁻³ (e.g., from 1×10¹⁵ cm⁻³ to 1×10¹⁹ cm⁻³, from 1×10¹⁹ cm⁻³ to 1×10²² cm⁻³ , from 1×10¹⁵ cm⁻³ to 1×10¹⁸ cm⁻³, from 1×10¹⁸ cm⁻³ to 1×10²⁰ cm⁻³, from 1×10²⁰ cm⁻³ to 1×10²² cm⁻³ , from 1×10¹⁵ cm⁻³ to 1×10²¹ cm⁻³, from 1×10¹⁵ cm⁻³ to 1×10²⁰ cm⁻³, from 1×10¹⁵ cm⁻³ to 1×10¹⁹ cm⁻³, from 5×10¹⁵ cm⁻³ to 1×10²² cm⁻³, 1×10¹⁶ cm⁻³ to 1×10²² cm⁻³, from 5×10¹⁶ cm⁻³ to 1×10²² cm⁻³, from 1×10¹⁷ cm⁻³ to 1×10²² cm⁻³, from 1×10¹⁸ cm⁻³ to 1×10²² cm⁻³, from 1×10¹⁹ cm⁻³ to 1×10²² cm⁻³, or from 5×10¹⁵ cm⁻³ to 5×10²¹ cm⁻³).

Also disclosed herein are methods of making any of the compositions disclosed herein. For example, also disclosed herein are methods comprising contacting a first precursor and a second precursor at a first temperature, wherein the first precursor comprises carbon and gallium, and the second precursor comprises oxygen, to thereby react the first precursor and the second precursor to form the composition comprising β-Ga₂O₃ doped with carbon. In some examples, the methods can comprise metal organic chemical vapor deposition (MOCVD), molecular-beam epitaxy (MBE), hydride vapor phase epitaxy (HVPE), pulsed laser deposition (PLD), low pressure chemical vapor deposition (LPCVD), mist-CVD, or a combination thereof. In some examples, the methods comprise metal organic chemical vapor deposition (MOCVD).

In some examples, the first precursor and/or the second precursor independently comprise(s) a fluid, such as a gas.

In some examples, the first precursor further comprises hydrogen and the composition optionally further comprises hydrogen.

In some examples, the first precursor comprises trimethylgallium (TMGa), triethylgallium (TEGa), Ga(DPM)₃ (DPM=dipivaloylmethanate), or a combination thereof. In some examples, the first precursor comprises trimethylgallium (TMGa).

In some examples, the first precursor is provided at a flow rate of 1 μmole/minute or more (e.g., for a 2 inch sized reactor) (e.g., 2 μmol/min or more, 3 μmol/min or more, 4 μmol/min or more, 5 μmol/min or more, 6 μmol/min or more, 7 μmol/min or more, 8 μmol/min or more, 9 μmol/min or more, 10 μmol/min or more, 15 μmol/min or more, 20 μmol/min or more, 25 μmol/min or more, 30 μmol/min or more, 35 μmol/min or more, 40 μmol/min or more, 45 μmol/min or more, 50 μmol/min or more, 55 μmol/min or more, 60 μmol/min or more, 65 μmol/min or more, 70 μmol/min or more, 75 μmol/min or more, 80 μmol/min or more, 85 μmol/min or more, 90 μmol/min or more, 95 μmol/min or more, 100 μmol/min or more, 105 μmol/min or more, 110 μmol/min or more, 115 μmol/min or more, 120 μmol/min or more, 125 μmol/min or more, 130 μmol/min or more, 135 μmol/min or more, 140 μmol/min or more, 145 μmol/min or more, 150 μmol/min or more, 155 μmol/min or more, 160 μmol/min or more, 165 μmol/min or more, 170 μmol/min or more, 175 μmol/min or more, 180 μmol/min or more, 185 μmol/min or more, 190 μmol/min or more, 195 μmol/min or more, 200 μmol/min or more, 205 μmol/min or more, 210 μmol/min or more, 215 μmol/min or more, 220 μmol/min or more, 225 μmol/min or more, 230 μmol/min or more, 235 μmol/min or more, 240 μmol/min or more, or 245 μmol/min or more). In some examples, the first precursor is provided at a flow rate of 250 μmole/minute or less (e.g., 245 μmol/min or less, 240 μmol/min or less, 235 μmol/min or less, 230 μmol/min or less, 225 μmol/min or less, 220 μmol/min or less, 215 μmol/min or less, 210 μmol/min or less, 205 μmol/min or less, 200 μmol/min or less, 195 μmol/min or less, 190 μmol/min or less, 185 μmol/min or less, 180 μmol/min or less, 175 μmol/min or less, 170 μmol/min or less, 165 μmol/min or less, 160 μmol/min or less, 155 μmol/min or less, 150 μmol/min or less, 145 μmol/min or less, 140 μmol/min or less, 135 μmol/min or less, 130 μmol/min or less, 125 μmol/min or less, 120 μmol/min or less, 115 μmol/min or less, 110 μmol/min or less, 105 μmol/min or less, 100 μmol/min or less, 95 μmol/min or less, 90 μmol/min or less, 85 μmol/min or less, 80 μmol/min or less, 75 μmol/min or less, 70 μmol/min or less, 65 μmol/min or less, 60 μmol/min or less, 55 μmol/min or less, 50 μmol/min or less, 45 μmol/min or less, 40 μmol/min or less, 35 μmol/min or less, 30 μmol/min or less, 25 μmol/min or less, 20 μmol/min or less, 15 μmol/min or less, 10 μmol/min or less, 9 μmol/min or less, 8 μmol/min or less, 7 μmol/min or less, 6 μmol/min or less, 5 μmol/min or less, 4 μmol/min or less, 3 μmol/min or less, or 2 μmol/min or less). The flow rate of the first precursor can range from any of the minimum values described above to any of the maximum values described above. For example, the first precursor can be provided at a flow rate of from 1 to 250 μmole/minute (e.g., from 1 to 125 μmol/min, from 125 to 250 μmol/min, from 1 to 50 μmol/min, from 50 to 100 μmol/min, from 100 to 150 μmol/min, from 150 to 200 μmol/min, from 200 to 250 μmol/min, from 5 to 250 μmol/min, from 10 to 250 μmol/min, from 15 to 250 μmol/min, from 20 to 250 μmol/min, from 25 to 250 μmol/min, from 30 to 250 μmol/min, from 40 to 250 μmol/min, from 50 to 250 μmol/min, from 75 to 250 μmol/min, from 100 to 250 μmol/min, from 125 to 250 μmol/min, from 1 to 225 μmol/min, from 1 to 200 μmol/min, from 1 to 175 μmol/min, from 1 to 150 μmol/min, from 1 to 125 μmol/min, from 1 to 100 μmol/min, from 1 to 75 μmol/min, from 1 to 50 μmol/min, from 5 to 225 μmol/min, from 10 to 200 μmol/min, from 15 to 175 μmol/min, from 20 to 150 μmol/min, from 25 to 125 μmol/min, or from 39 to 116 μmol/min).

In some examples, the second precursor comprises O₂.

In some examples, the first temperature is 550 °C or more (e.g., 575 °C or more, 600 °C or more, 625 °C or more, 650 °C or more, 675 °C or more, 700 °C or more, 725 °C or more, 750 °C or more, 775 °C or more, 800 °C or more, 825 °C or more, 850 °C or more, 875 °C or more, 900 °C or more, 925 °C or more, 950 °C or more, 975 °C or more, 1000 °C or more, 1025 °C or more, 1050 °C or more, or 1075 °C or more). In some examples, the first temperature is 1200 °C or less (e.g., 1075 °C or less, 1050 °C or less, 1025 °C or less, 1000 °C or less, 975 °C or less, 950 °C or less, 925 °C or less, 900 °C or less, 875 °C or less, 850 °C or less, 825 °C or less, 800 °C or less, 775 °C or less, 750 °C or less, 725 °C or less, 700 °C or less, 675 °C or less, 650 °C or less, 625 °C or less, 600 °C or less, or 575 °C or less). The first temperature can range from any of the minimum values described above to any of the maximum values described above. For example, the first temperature can be from 550 °C to 1200 °C (e.g., From 550 °C to 725 °C, from 725 °C to 1000 °C, from 1000 °C to 1200 °C, from 550 °C to 650 °C, from 650 °C to 750 °C, from 750 °C to 850 °C, from 850 °C to 1000 °C, from 1000 °C to 1100 °C, from 1100 °C to 1200 °C, from 550 °C to 1150 °C, from 550 °C to 1100 °C, from 550 °C to 1050 °C, from 550 °C to 1000 °C, from 550 °C to 950 °C, from 550 °C to 900 °C, from 550 °C to 850 °C, from 550 °C to 800 °C, from 550 °C to 750 °C, from 550 °C to 700 °C, from 550 °C to 650 °C, from 600 °C to 1200 °C, from 650 °C to 1200 °C, from 700 °C to 1200 °C, from 750 °C to 1200 °C, from 800 °C to 1200 °C, from 850 °C to 1200 °C, from 900 °C to 1200 °C, from 950 °C to 1200 °C, from 1000 °C to 1200 °C, from 1050 °C to 1200 °C, from 1100 °C to 1200 °C, from 600 °C to 1000 °C, from 650 °C to 1000 °C, from 700 °C to 1000 °C, from 750 °C to 1000 °C, from 800 °C to 1000 °C, from 850 °C to 1000 °C, from 900 °C to 1000 °C, from 600 °C to 1150 °C, from 600 °C to 950 °C, or from 700 °C to 950 °C).

The flow rate of the first precursor, the first temperature, or a combination thereof can independently be selected in view of a variety of factors. For example, flow rate of the first precursor, the first temperature, or a combination thereof can independently be selected in view of the desired amount of carbon in the resulting composition. For example, the methods can further comprise controlling the flow rate of the first precursor, the temperature, or a combination thereof to thereby control the concentration of carbon in the resulting composition. For example, the methods can further comprise controlling the flow rate of the first precursor, the temperature, or a combination thereof to thereby control the concentration of carbon and optionally hydrogen in the resulting composition.

In some examples, the method produces the composition at a growth rate of 0.2 micrometers per hour (μm/hour) or more (e.g., 0.3 μm/hour or more, 0.4 μm/hour or more, 0.5 μm/hour or more, 0.75 μm/hour or more, 1 μm/hour or more, 1.25 μm/hour or more, 1.5 μm/hour or more, 1.75 μm/hour or more, 2 μm/hour or more, 2.25 μm/hour or more, 2.5 μm/hour or more, 2.75 μm/hour or more, 3 μm/hour or more, 3.25 μm/hour or more, 3.5 μm/hour or more, 3.75 μm/hour or more, 4 μm/hour or more, 4.25 μm/hour or more, 4.5 μm/hour or more, 4.75 μm/hour or more, 5 μm/hour or more, 5.25 μm/hour or more, 5.5 μm/hour or more, 5.75 μm/hour or more, 6 μm/hour or more, 6.25 μm/hour or more, 6.5 μm/hour or more, 6.75 μm/hour or more, 7 μm/hour or more, 7.25 μm/hour or more, 7.5 μm/hour or more, 7.75 μm/hour or more, 8 μm/hour or more, 8.25 μm/hour or more, 8.5 μm/hour or more, 8.75 μm/hour or more, 9 μm/hour or more, 9.25 μm/hour or more, 9.5 μm/hour or more, 9.75 μm/hour or more, 10 μm/hour or more, 10.5 μm/hour or more, 11 μm/hour or more, 11.5 μm/hour or more, 12 μm/hour or more, 12.5 μm/hour or more, 13 μm/hour or more, 13.5 μm/hour or more, 14 μm/hour or more, 14.5 μm/hour or more, 15 μm/hour or more, 15.5 μm/hour or more, 16 μm/hour or more, 16.5 μm/hour or more, 17 μm/hour or more, 17.5 μm/hour or more, 18 μm/hour or more, 18.5 μm/hour or more, 19 μm/hour or more). In some examples, the method produces the composition at a growth rate of 20 μm/hour or less (e.g., 19.5 μm/hour or less, 19 μm/hour or less, 18.5 μm/hour or less, 18 μm/hour or less, 17.5 μm/hour or less, 17 μm/hour or less, 16.5 μm/hour or less, 16 μm/hour or less, 15.5 μm/hour or less, 15 μm/hour or less, 14.5 μm/hour or less, 14 μm/hour or less, 13.5 μm/hour or less, 13 μm/hour or less, 12.5 μm/hour or less, 12 μm/hour or less, 11.5 μm/hour or less, 11 μm/hour or less, 10.5 μm/hour or less, 10 μm/hour or less, 9.75 μm/hour or less, 9.5 μm/hour or less, 9.25 μm/hour or less, 9 μm/hour or less, 8.75 μm/hour or less, 8.5 μm/hour or less, 8.25 μm/hour or less, 8 μm/hour or less, 7.75 μm/hour or less, 7.5 μm/hour or less, 7.25 μm/hour or less, 7 μm/hour or less, 6.75 μm/hour or less, 6.5 μm/hour or less, 6.25 μm/hour or less, 6 μm/hour or less, 5.75 μm/hour or less, 5.5 μm/hour or less, 5.25 μm/hour or less, 5 μm/hour or less, 4.75 μm/hour or less, 4.5 μm/hour or less, 4.25 μm/hour or less, 4 μm/hour or less, 3.75 μm/hour or less, 3.5 μm/hour or less, 3.25 μm/hour or less, 3 μm/hour or less, 2.75 μm/hour or less, 2.5 μm/hour or less, 2.25 μm/hour or less, 2 μm/hour or less, 1.75 μm/hour or less, 1.5 μm/hour or less, or 1.25 μm/hour or less). The growth rate at which the method produced the composition can range from any of the minimum values described above to any of the maximum values described above. For example, the method can produce the composition at a growth rate of from 0.2 to 20 μm/hour (e.g., from 0.2 to 10 μm/hour, from 10 to 20 μm/hour, from 0.2 to 5 μm/hour, from 5 to 10 μm/hour, from 10 to 15 μm/hour, from 15 to 20 μm/hour, from 0.2 to 15 μm/hour, from 0.2 to 12.5 μm/hour, from 0.2 to 7.5 μm/hour, from 0.2 to 2.5 μm/hour, from 0.2 to 1 μm/hour, from 0.5 to 20 μm/hour, from 1 to 20 μm/hour, from 2.5 to 20 μm/hour, from 5 to 20 μm/hour, from 7.5 to 20 μm/hour, from 12.5 to 20 μm/hour, from 17.5 to 20 μm/hour, from 0.5 to 19.5 μm/hour, from 1 to 15 μm/hour, from 1 to 10 μm/hour, from 1 to 5 μm/hour, from 5 to 10 μm/hour, from 1 to 2.5 μm/hour, from 2.5 to 5 μm/hour, from 5 to 7.5 μm/hour, from 7.5 to 10 μm/hour, from 1 to 9 μm/hour, from 1 to 8 μm/hour, from 1 to 7 μm/hour, from 1 to 6 μm/hour, from 1 to 5 μm/hour, from 1 to 4 μm/hour, from 1 to 3 μm/hour, from 1.5 to 10 μm/hour, from 2 to 10 μm/hour, from 2.5 to 10 μm/hour, from 3 to 10 μm/hour, from 4 to 10 μm/hour, from 5 to 10 μm/hour, from 6 to 10 μm/hour, from 7 to 10 μm/hour, from 1.25 to 9 μm/hour, from 1.5 to 8 μm/hour, from 2 to 6.75 μm/hour, or from 2 to 3.25 μm/hour). In some examples, the flow rate of the first precursor and/or the second precursor, the first temperature, or a combination thereof can independently be chosen in view of the desired growth rate.

In some examples, the method is conducted at a pressure of 1 torr or more (e.g., 5 torr or more, 10 torr or more, 15 torr or more, 20 torr or more, 25 torr or more, 30 torr or more, 35 torr or more, 40 torr or more, 45 torr or more, 50 torr or more, 55 torr or more, 60 torr or more, 65 torr or more, 70 torr or more, 75 torr or more, 80 torr or more, 85 torr or more, 90 torr or more, 95 torr or more, 100 torr or more, 105 torr or more, 110 torr or more, 115 torr or more, 120 torr or more, 125 torr or more, 130 torr or more, 135 torr or more, 140 torr or more, 145 torr or more, 150 torr or more, 155 torr or more, 160 torr or more, 165 torr or more, 170 torr or more, 175 torr or more, 180 torr or more, 185 torr or more, 190 torr or more, or 195 torr or more). In some examples, the method is conducted at a pressure of 200 torr or less (e.g., 195 torr or less, 190 torr or less, 185 torr or less, 180 torr or less, 175 torr or less, 170 torr or less, 165 torr or less, 160 torr or less, 155 torr or less, 150 torr or less, 145 torr or less, 140 torr or less, 135 torr or less, 130 torr or less, 125 torr or less, 120 torr or less, 115 torr or less, 110 torr or less, 105 torr or less, 100 torr or less, 95 torr or less, 90 torr or less, 85 torr or less, 80 torr or less, 75 torr or less, 70 torr or less, 65 torr or less, 60 torr or less, 55 torr or less, 50 torr or less, 45 torr or less, 40 torr or less, 35 torr or less, 30 torr or less, 25 torr or less, 20 torr or less, 15 torr or less, 10 torr or less, or 5 torr or less). The pressure at which the method is conducted can range from any of the minimum values described above to any of the maximum values described above. For example, the method can be conducted at a pressure of from 1 to 200 torr (e.g., from 1 to 100 torr, from 100 to 200 torr, from 1 to 50 torr, from 50 to 100 torr, from 100 to 150 torr, from 150 to 200 torr, from 1 to 175 torr, from 1 to 150 torr, from 1 to 125 torr, from 1 to 75 torr, from 1 to 25 torr, from 1 to 10 torr, from 5 to 200 torr, from 10 to 200 torr, from 25 to 200 torr, from 50 to 200 torr, from 75 to 200 torr, from 125 to 200 torr, from 150 to 200 torr, from 5 to 175 torr, from 5 to 150 torr, from 5 to 100 torr, from 5 to 60 torr, from 5 to 30 torr, from 30 to 60 torr, from 5 to 15 torr, from 15 to 30 torr, from 30 to 45 torr, from 45 to 60 torr, from 5 to 55 torr, from 5 to 50 torr, from 5 to 45 torr, from 5 to 40 torr, from 5 to 35 torr, from 5 to 30 torr, from 5 to 25 torr, from 5 to 20 torr, from 5 to 15 torr, from 10 to 60 torr, from 15 to 60 torr, from 20 to 60 torr, from 25 to 60 torr, from 30 to 60 torr, from 35 to 60 torr, from 40 to 60 torr, from 45 to 60 torr, from 50 to 60 torr, from 10 to 55 torr, or from 15 to 50 torr).

In some examples, the method further comprises introducing a third precursor comprising an additional dopant, such that the composition further comprises the additional dopant. In some examples, the third precursor is provided as a fluid, such as a gas. In some examples, the third precursor comprises silane (SiH₄), germane (GeH₄), disilane (Si₂H₆), bis(cyclopentadienyl)magnesium (Cp₂Mg), bis(methylcyclopentadienyl)magnesium ((MeCp)₂Mg), or a combination thereof. In some examples, the third precursor comprises silane (SiH₄).

In some examples, the first precursor, the second precursor, the third precursor (when present), or a combination thereof are independently provided with a carrier gas. In some examples, the carrier gas comprises argon, helium, N2, and the like, or combinations thereof.

Also disclosed herein are compositions made by any of the methods disclosed herein.

Also disclosed herein are devices comprising any of the compositions disclosed herein. For example, the device can comprise a MESFET device, a MODFET device, a MOSFET device, a Current Aperture Vertical Electron Transistor (CAVET) device, or a combination thereof. In some examples, the device comprises a vertical power device. In some examples, the device comprises an optical device, an electronic device, an optoelectronic device, or a combination thereof. In some examples, the device comprises a diode.

Also disclosed herein are methods of use of any of the compositions disclosed herein.

A number of embodiments of the invention have been described. Nevertheless, it will be understood that various modifications may be made without departing from the spirit and scope of the invention. Accordingly, other embodiments are within the scope of the following claims.

The examples below are intended to further illustrate certain aspects of the devices and methods described herein, and are not intended to limit the scope of the claims.

### EXAMPLES

The following examples are set forth below to illustrate the methods and results according to the disclosed subject matter. These examples are not intended to be inclusive of all aspects of the subject matter disclosed herein, but rather to illustrate representative methods and results. These examples are not intended to exclude equivalents and variations of the present invention which are apparent to one skilled in the art.

Efforts have been made to ensure accuracy with respect to numbers (e.g., amounts, temperature, etc.) but some errors and deviations should be accounted for. Unless indicated otherwise, parts are parts by weight, temperature is in °C or is at ambient temperature, and pressure is at or near atmospheric. There are numerous variations and combinations of measurement conditions, e.g., component concentrations, temperatures, pressures and other measurement ranges and conditions that can be used to optimize the described process.

### Example 1

### Formation of Carbon Containing Semi-Insulating Layers in β-Ga₂O₃ Based Structures and Devices

Beta-gallium oxide (β-Ga₂O₃), with its ultrawide band gap energy (~4.8 eV), high predicted breakdown field strength (6-8 MV/cm), controllable n-type doping and availability of large area, high quality melt-grown native substrates, has spurred substantial interest for applications in high power/high frequency electronics and ultraviolet optoelectronics [1]. The ability of bandgap engineering by alloying with Al₂O₃ also extends its applications into new regime with even higher critical field strength (~16 MV/cm at Al<80%) and even shorter wavelength regime that is currently unachievable from SiC or GaN based devices [2,3]. Considering this material's immense potential in high power and high frequency electronic applications, epitaxial growths of high quality β-Ga₂O₃ and β-(AlₓGa₁₋ₓ)₂O₃ alloys have been demonstrated by different growth methods on different crystal orientations. Despite the fact that p-type doping appears to be challenging in β-Ga₂O₃ due to negligible valence band dispersion, strong hole self-localization, and large acceptor ionization energies [4], various device designs could still take advantage of its high-breakdown field strength and achieve normally-off operation. Vertical fin-shaped channel metal-insulator-semiconductor (MIS) field effect transistors (FinFETs) with normally-off operation, for example, could withstand more than 2 kV of breakdown voltage [5]. Schottky barrier diode (SBD) with a similar vertical fin structure is demonstrated with a breakdown voltage of 2.89 kV with Baliga's figure-of-merit (BFOM) of 0.80 GW/cm²(BV₂/R_{on,sp}) [6]. In addition, motivated by the excellent transistor performance of current aperture vertical electron transistor (CAVET) in GaN power electronics, enhancement-mode (E-mode) vertical β-Ga₂O₃ metal-oxide-semiconductor (MOS) field-effect transistors containing a current aperture have been demonstrated with high output current on/off ratio by using nitrogen-ion-implanted current blocking layer for vertical source-drain isolation [7]. One crucial aspect in these device designs is to introduce a charge compensation or current blocking layer (CBL) in the desired device region. In the absence of effective p-type doping in β-Ga₂O₃, an alternative route is to employ semi-insulating layer to engineer the electric field in power devices and also to suppress the substrate/epilayer interface charges.

The presence of interface charges at the substrate/epilayer growth interface is a common phenomenon in β-Ga₂O₃ and β-(AlₓGa₁₋ₓ)₂O₃ epitaxy. The existence of the spike of Si peak at the growth interface have been observed by different growth methods, including metalorganic chemical vapor deposition (MOCVD) [8] and molecular beam epitaxy (MBE) [9], likely caused by the substrate polishing process and/or contamination from atmosphere and cleaning processes. Such interface charges can be detrimental to the device performances by causing buffer leakage current in lateral electronic devices. The suppression of these interface charges can significantly improve the device performance by preventing premature breakdown of the devices. Thus far, different methods have been proposed to make semi-insulating regions of devices to create current blocking layers and to compensate the accumulated substrate/epilayer interface charges, including in-situ epitaxial growth of semi-insulating β-Ga₂O₃ layer by doping with Mg [9, 10], Fe [11] or N [12] as well as ex-situ ion-implantation process [13]. While Mg doped semi-insulating β-Ga₂O₃ films was reported to successfully compensate the growth interface charges, high diffusion of Mg adatoms on growth surface leads to the complications for the precise control of carrier concentrations in the channel layer [10] and interfaces. While Fe is commonly used to produce semi-insulating substrates, the controllable Fe doping in β-Ga₂O₃ was found to be difficult due to significant surface segregation from the substrate during epitaxial growth [11]. On the other hand, ex-situ ion-implantation process using N or Mg as acceptor dopants also causes severe damage to the target crystal and large diffusion during thermal annealing process for recovering the ion implantation damage [13]. Controllable acceptor doping with lower diffusion of dopants is needed to produce high quality semi-insulating regions of devices for compensating interface charges and to create current blocking layers.

There has been no prior demonstration of forming semi-insulating β-Ga₂O₃ layers without applying any additional acceptors by any growth methods. Herein, a method is described for developing carbon containing semi-insulating β-Ga₂O₃ layers using trimethylgallium (TMGa) as the Ga precursor, wherein the methods tune only the growth conditions and precursor flow rates without introducing any additional acceptors in the growth chamber. TMGa is a common metalorganic precursor in MOCVD process. However, the methods described herein do not exclude other growth techniques such as MBE, hydride vapor phase epitaxy (HVPE), pulsed laser deposition (PLD), low pressure chemical vapor deposition (LPCVD) and etc. Herein, the MOCVD growth of C-containing semi-insulating β-Ga₂O₃ layer on Ga₂O₃ substrates is use as an example.

In this demonstration, for the MOCVD growth, trimethylgallium (TMGa) and pure O₂ were used as the Ga and O precursors, respectively. Argon (Ar) was used as the carrier gas. The typical growth temperature was varied between 550-1000 °C, and the typical chamber pressure was varied between 5 and 600 torr.

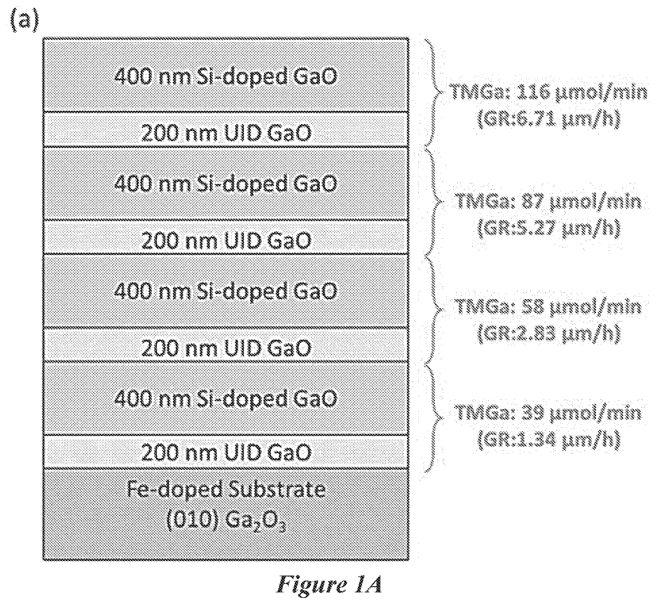

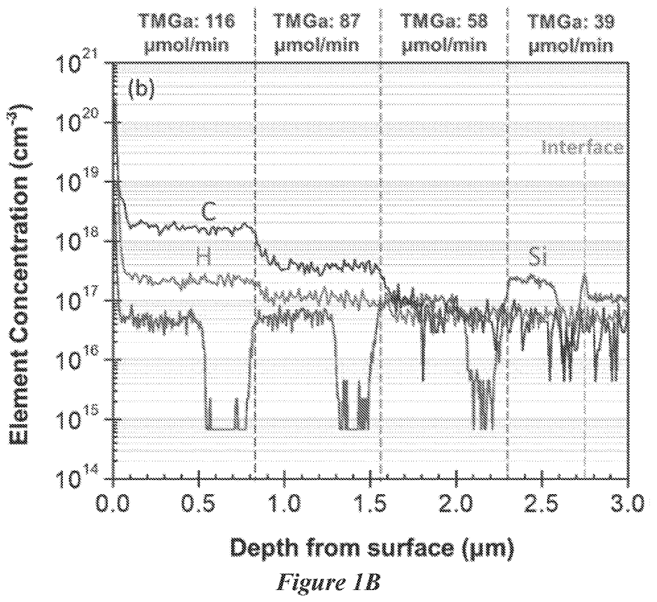

FIG. 1A-FIG. 1B show the structures and SIMS impurity profiles of β-Ga₂O₃ sample grown with different TMGa flow rates. The silane molar flow rate was set at 0.416 nmol/min for Si-doped layers. The growth temperature and chamber pressure were kept constant at 950 °C and 60 torr, respectively. FIG. 1A shows a schematic of a multi-layer stack of both Si and unintentionally doped β-Ga₂O₃ layers grown for quantitative secondary ion mass spectroscopy (SIMS) characterizations (FIG. 1B) using the same silane (0.416 nmole/min) but different TMGa flow rates ranging from 39-116 μmole/min. As the TMGa molar flow rate increases, the β-Ga₂O₃ thin film growth rate increases under the investigated growth conditions.

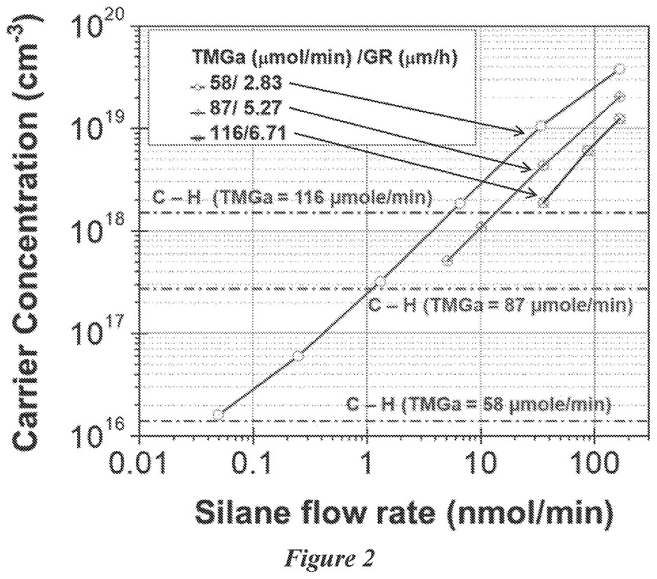

The SIMS depth profile shows a significant increase of carbon and hydrogen impurity concentrations as the TMGa molar flow rate increases, while a slight decrease of Si concentrations is observed with the increase of TMGa flow rate. The influence of the incorporations of Si, C, and H impurities for different TMGa molar flow rates on resulting net carrier concentrations are also investigated by Hall measurements as shown in FIG. 2 for different growth rates of 2.83, 5.27 and 6.71 μm/hr, respectively. While the net carrier concentrations can be tuned over a wide range in lower growth rate β-Ga₂O₃ samples with relatively low TMGa flow rate, the doping range becomes narrower as the growth rate increases with higher TMGa flow rates. This can be correlated with the increase of C and H impurity concentrations as observed from SIMS characterization. The higher level of C impurity concentration provides effective compensation of Si for various growth rates, forming controllable semi-insulating β-Ga₂O₃ layer up to certain level of silane flow rates for different TMGa flows. However, H impurity also plays a critical role in this case. The easy formation of neutral C—H complex in MOCVD β-Ga₂O₃ growth will deactivate the compensation role of C, as predicted from density functional theory (DFT) [14]. Therefore, if the H concentration is similar or higher than C, it is likely that C—H is the dominant impurity complex and C does not serve as effective compensation center. Here, it is proposed to control TMGa flow rate to effectively control the C, H incorporation in MOCVD β-Ga₂₃. As shown in FIG. 1A-FIG. 1B, as TMGa flow rate increases, C concentration can exceed H concentration, and therefore the net C concentration ([C]−[H]) can serve as effective compensation centers. This serves as a very effective approach to in-situ grow an insulating β-Ga₂O₃ layer without intentionally introducing acceptors. This approach can ensure the formation of sharp interfaces between insulating and non-insulating layers.

In addition to using TMGa flow rate to tune the C and H incorporation concentrations, it is also proposed to use growth temperature as an effective approach.

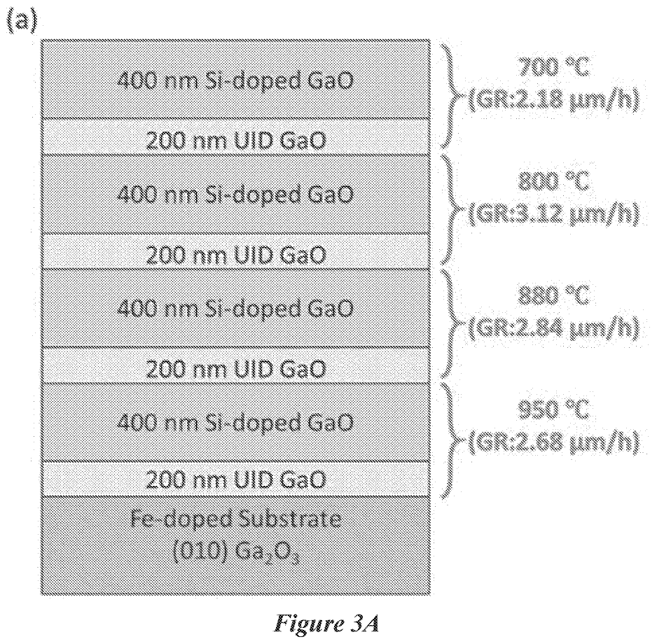

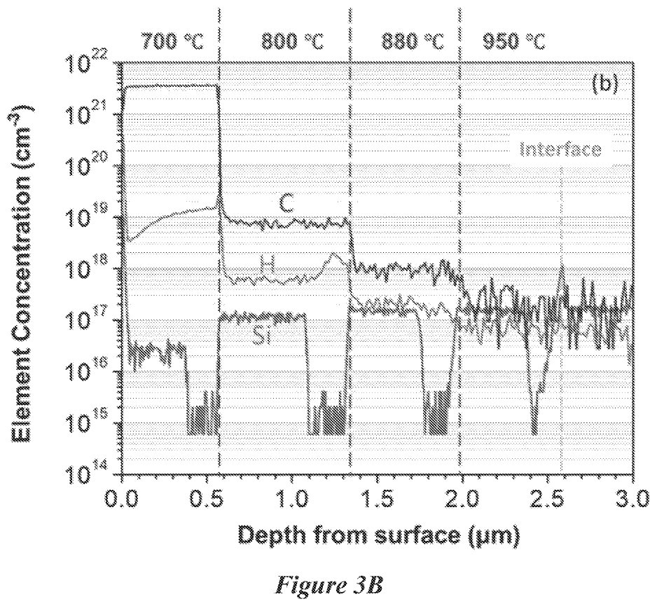

Structures and SIMS impurity profiles of TMGa grown β-Ga₂O₃ sample for different growth temperature are shown in FIG. 3A and FIG. 3B, respectively. The Silane molar flow rate was set at 0.416 nmol/min for Si-doped layers. The TMGa molar flow rate and chamber pressure were 58 μmol/min and 60 torr, respectively.

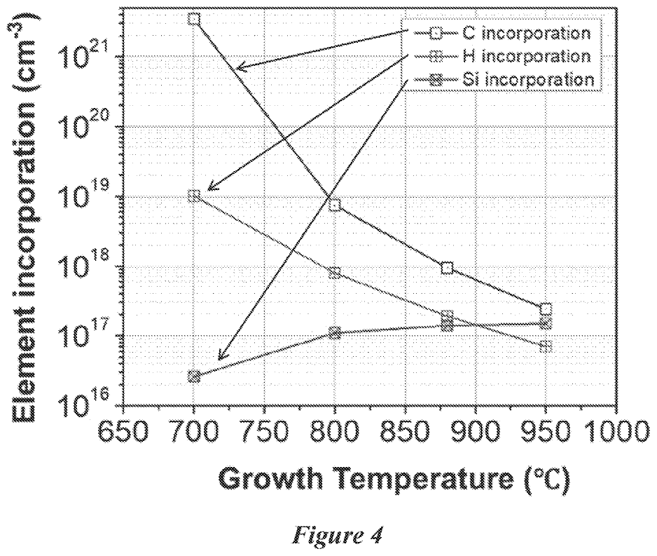

As shown in FIG. 3B, the quantitative SIMS measures the influence of the growth temperature on C and H impurity incorporation. The SIMS depth profile of TMGa grown Si doped β-Ga₂O₃ layers at different growth temperature of 700-950 °C reveals a sharp increase of C and H levels as the growth temperature reduces from 950 °C to 700 °C (FIG. 4), indicating that higher level of charge compensation can be achieved at lower growth temperature. No diffusions of C and Hadatoms are observed from the symmetrical distributions of SIMS depth profile, revealing the promises for developing high performance lateral devices by creating high quality semi-insulating β-Ga₂O₃ buffer layer for suppressing the substrate/epilayer interface charge or forming high potential barriers and current blocking layers in vertical devices.

To summarize, the methods described herein form semi-insulating β-Ga₂O₃ layers via effective tuning of C and H incorporation. In MOCVD growth method, tuning TMGa and growth temperature represent two effective approaches to control the C and H incorporation. As TMGa molar flow rate increases or growth temperature decreases, C and H incorporation increase.

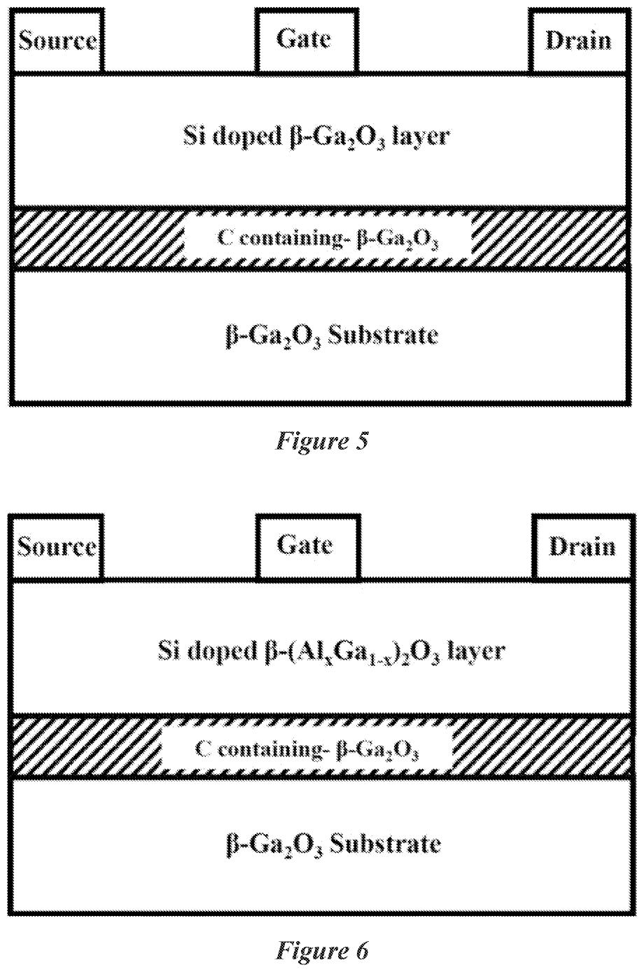

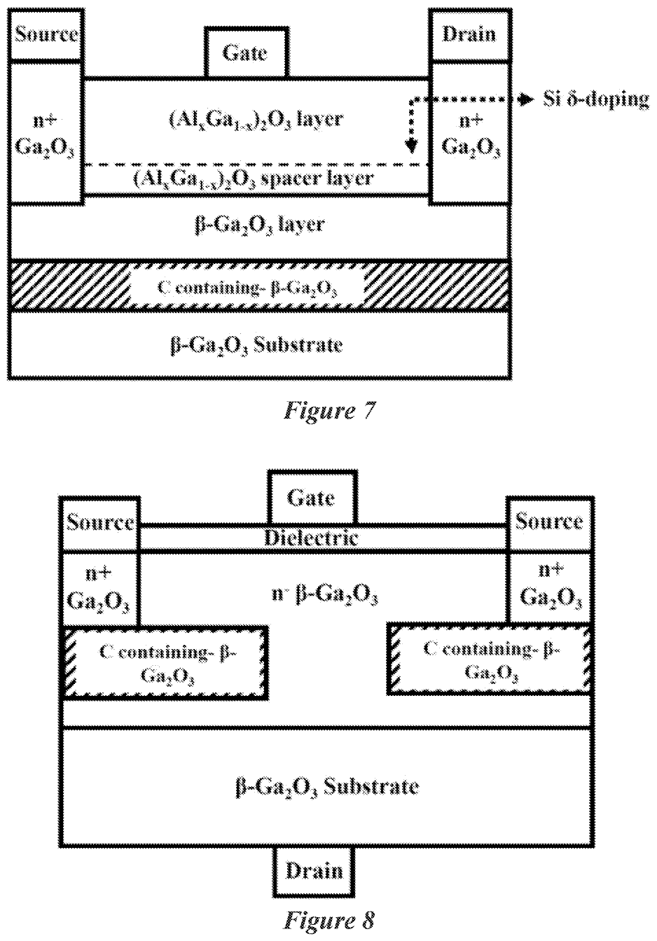

Based on this idea, device structures requiring semi-insulating layer or current blocking layer can incorporate the methods described above. For example, β-Ga₂O₃ (FIG. 5) and β-(AlₓGa₁₋ₓ)₂O₃ (FIG. 6) based MESFETs or β-Ga₂O₃/(AlₓGa₁₋ₓ)₂O₃ based MODFET structures (FIG. 7) using semi-insulating TMGa grown β-Ga₂O₃ buffer layer to compensate the substrate/interface charges. Using the methods described herein, the semi-insulating layers can also be incorporated to develop Current Aperture Vertical Electron Transistor (CAVET) as shown in FIG. 8 by forming the current blocking layer using TMGa grown semi-insulating β-Ga₂O₃ that can block the current from flowing through any other direction but the aperture. These structures can be applicable for optoelectronic and electronic power devices.

Described herein is the formation of carbon doped semi-insulating β-Ga₂O₃ layer without introducing any additional acceptors will provide a new route to develop both lateral electronic devices and vertical power devices which require one or more semi-insulating layers.

### References

1. Green et al., APL Materials 10, 029201 (2022).
2. J B Varley, J. Mater. Res. 36, 4790 (2021).
3. AFMAU Bhuiyan et al. Cryst. Growth Des. 20, 6722 (2020).
4. H. Peelaers et al. Phys. Status Solidi B 252(4), 828 (2015).
5. W. Li et al. 2019 IEEE International Electron Devices Meeting, San Francisco, CA, USA, December 2019.
6. W. Li et al. IEEE Electron Device Lett. 41, 107 (2020).
7. M. H. Wong et al. IEEE Electron Device Lett. 41, 296 (2020).
8. Z. Feng et al. Phys. Status Solidi RRL 14, 2000145 (2020).
9. A. Mauze et al. J. Appl. Phys. 130, 235301 (2021).
10. Z. Feng et al. Appl. Phys. Lett. 117, 222106 (2020).
11. A. Mauze et al. Appl. Phys. Lett. 115(5), 052102 (2019).
12. F. Alema et al. and J. S. Speck, APL Mater. 8, 021110 (2020).
13. M. H. Wong et al. Appl. Phys. Lett. 113, 102103 (2018).
14. S. Mu et al. Phys. Rev. B 105, 155201 (2022).

### Example 2

### Role of Carbon in MOCVD β-Ga₂O₃ Using TMGa as Precursor

Herein, the role of background carbon in metalorganic chemical vapor deposition (MOCVD) β-Ga₂O₃ growth using trimethylgallium (TMGa) as the Ga precursor was investigated. The quantitative C and H incorporations in MOCVD β-Ga₂O₃ thin films grown at different growth rate and temperature were measured via quantitative secondary ion mass spectroscopy (SIMS). The SIMS results revealed both [C] and [H] increase as the TMGa molar flow rate/growth rate increases or growth temperature decreases. The intentional Si incorporation in MOCVD β-Ga₂O₃ thin films decreases as the growth rate increases or the growth temperature decreases. For films grown at relatively fast growth rates (GR) (TMGa>58 μmol/min, growth rate>2.8 μm/h) or relatively low temperature (<950 °C), the [C] increases faster than that of the [H]. The experimental results from this study demonstrate the previously predicted theory—H can effectively passivate the compensation effect of C in n-type β-Ga₂O₃. The extracted net doping concentration from quantitative SIMS ([Si]−([C]−[H])) agrees well with the free carrier concentration measured from Hall measurement. The revealing of the role of C compensation in MOCVD β-Ga₂O₃ and effect of H incorporation can provide guidance on designing material synthesis for targeted device applications.

β-Ga₂O₃ has been considered as a promising semiconductor candidate for high power and radio frequency (RF) electronics because of its ultrawide energy bandgap (4.8 eV) and predicted high critical field strength (8 MV/cm) [1-3]. Yet, the material is n-type dopable with shallow donors and a wide range of doping concentration from 10¹⁶ cm⁻³ to 10²⁰ cm⁻³ [4-8]. The availability of high crystalline quality Ga₂O₃ substrates [9] with different orientations ((010), (100), (001), (−201)) enables high quality epitaxy of β-Ga₂O₃ [5-7, 10-27] and β-AlGaO [28-34]. Several growth methods have been used to develop β-Ga₂O₃ thin films including molecular beam epitaxy (MBE) [6, 11, 35, 36], pulsed laser deposition (PLD) [37-39], halide vapor phase epitaxy (HVPE) [5, 40-42], low pressure chemical vapor deposition (LPCVD) [8, 14, 43-45] and metalorganic chemical vapor deposition (MOCVD) [4, 7, 16, 17, 23, 25, 46-48]. Among them, MOCVD has been demonstrated to produce high crystalline quality materials with record room temperature and low temperature mobilities that approach the theoretical values [7, 20, 23, 49]. The typical growth rate for MOCVD-Ga₂O₃ using triethylgallium (TEGa) as the Ga precursor ranges between 0.2-1.0 μm/h [17, 23, 48, 49]. For devices requiring thick epi-layers, such as vertical power devices, epi-films with fast growth rate and high crystalline quality are required. Current device demonstrations on vertical β-Ga₂O₃ Schottky diodes or vertical pn diodes with thick drift layers are mainly based on HVPE grown materials [13, 50-56]. However, due to rough and non-uniform surface morphologies of HVPE grown β-Ga₂O₃ [41], chemical-mechanical polishing process is required for device processing, which can cause impurities incorporation and prevent in-situ epitaxy of heterojunctions.

On the other hand, MOCVD growth of β-Ga₂O₃ using trimethylgallium (TMGa) as the Ga precursor on (010) Ga₂O₃ substrates has been demonstrated with relatively fast growth rate up to ~3 μm/h [25]. Room temperature mobility as high as 190cm²/Vs with carrier concentration of 1.8×10¹⁶ cm⁻³ and compensation level of ~1.5×10¹⁵ cm⁻³ was achieved [25]. Previously, MOCVD growth of (010) β-Ga₂O₃ using TMGa with growth rate of 1.5 μm/h reported room temperature mobility of 125 cm²/Vs with carrier concentration of 1.5×10¹⁶ cm⁻³, and low temperature peak mobility of 23000 cm²/Vs at 32 K [20]. These results indicate a great potential to develop high quality thick β-Ga₂O₃ films via MOCVD using TMGa as the Ga precursor. As compared to TEGa (3 torr at 20 °C), TMGa has a higher vapor pressure (65 torr at 0 °C) [57] and a shorter reaction pathway (in contrast to TEGa, which undergoes a three-step decomposition process, TMGa pyrolyzes via a two-step unimolecular reaction, generating monomethylgallium and a methyl group as by-products) [20, 58, 59], which enables faster growth rates of β-Ga₂O₃. Carbon (C) is considered as one of the most common impurities in MOCVD grown materials as it originates from the metalorganic (MO) precursors. Particularly, C incorporation is higher using TMGa as compared to that of the TEGa. TEGa decomposes via β-elimination and has a lower decomposition temperature, thus lowering carbon incorporation into the surface during MOCVD growth [60]. It was well understood that C is one of the main sources of charge compensation in the MOCVD grown n-type GaN [61, 62]. However, the role of C in MOCVD growth of β-Ga₂O₃ is still not well understood.

In this work, C incorporation in MOCVD grown β-Ga₂O₃ on (010) Ga₂O₃ substrates using TMGa as the Ga precursor is systematically studied as a function of the growth rate and growth temperature. TMGa and pure O₂ were used as the precursors of Ga and O, respectively. Argon was used as the carrier gas. Si doping was introduced by using the diluted silane source (25 ppm) in the Si-doped samples. The growth pressure was set at 60 Torr and the O₂ flow rate was set at 800 standard cubic centimeter per minute (sccm). The TMGa molar flow rate was varied between 39 μmol/min and 116 μmol/min. The growth temperature was controlled between 700 °C and 950 °C. All samples were grown on Fe-doped semi-insulating (010) β-Ga₂O₃ substrates, which were ex-situ cleaned with acetone, IPA, and DI-water prior loading to the growth chamber. Quantitative secondary ion mass spectroscopy (SIMS) was used to probe the impurity profiles of C, hydrogen (H), and silicon (Si). Room temperature carrier transport characteristics were measured via van der Pauw Hall measurement (Ecopia HMS 3000, magnetic field=0.975 T). Ti/Au (30/100 nm) contacts were deposited on the four corners of the sample and annealed at 470 °C under N₂ for 1 min to obtain Ohmic contacts.

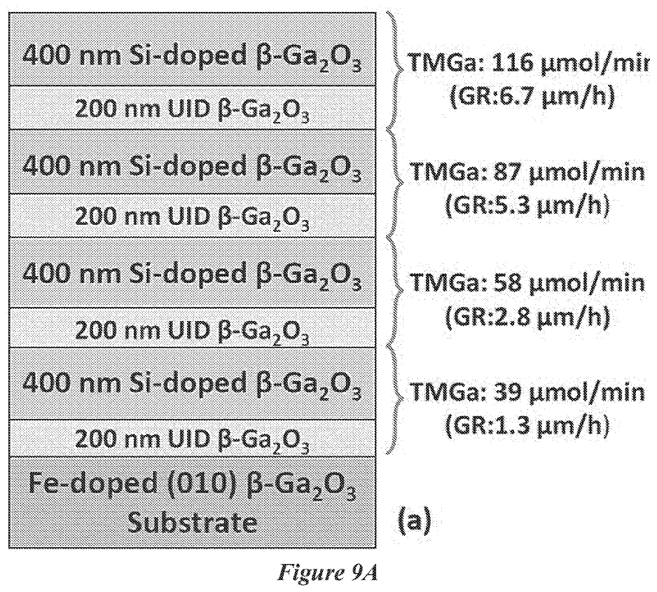

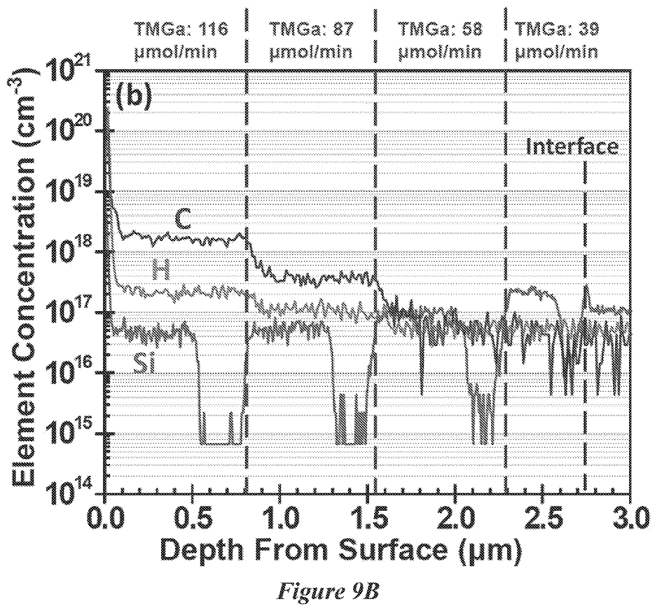

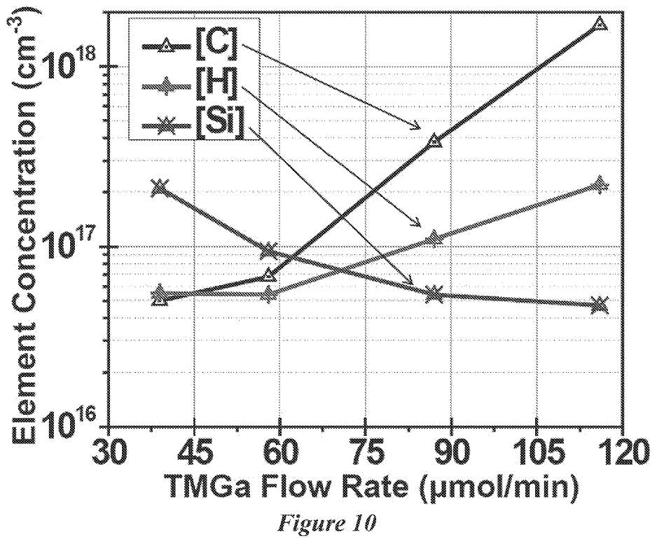

The impurity concentrations of C, Si and H, as a function of the TMGa molar flow rate was studied by quantitative SIMS on a multi-layer stack sample (stack I) as shown in FIG. 9A. The growth temperature was kept at 950 °C. The silane flow rate was set at 0.416 nmol/min in the Si-doped sub-layers, which were sandwiched between the un-intentionally doped (UID) layers. The TMGa molar flow rate was varied from 39 to 116 μmol/min. FIG. 9B shows the SIMS depth profiles of the impurity elements C, H and Si. The detection limit for C, H and Si is 3×10¹⁶ cm⁻³, 5×10¹⁶ cm⁻³, and 5×10¹⁵ cm⁻³, respectively. The β-Ga₂O₃ growth rate under different TMGa flow rate was extracted from the SIMS depth profiles. It increases from 1.3 μm/h to 6.7 μm/h with the TMGa molar flow rate tuned from 39 μmol/min to 116 μmol/min. From FIG. 9B, an obvious monotonic increase of both [C] and [H] was observed as the β-Ga₂O₃ growth rate increases. Both [C] and [H] does not show dependence on the Si doping within the sub-layers grown at the same TMGa flow rate. The background Si in the UID sub-layers was below or at the Si SIMS detection limit (5×10¹⁵ cm⁻³). FIG. 10 plots the [Si], [C] and [H] as a function of the TMGa molar flow rate. As the TMGa flow rate increases, [C] increases at a faster rate as compared to that of [H]. The [C] increases from 4.1×10¹⁶ cm⁻³ to 1.7×10¹⁸ cm⁻³, as the TMGa flow rate increases from 39 μmol/min to 116 μmol/min. The [Si] decreases as the TMGa flow rate increases due to the reduction of Si adatom concentration at the growth surface. On the other hand, the companion increase of [H] with [C] indicates the possibility of C—H complex formation.

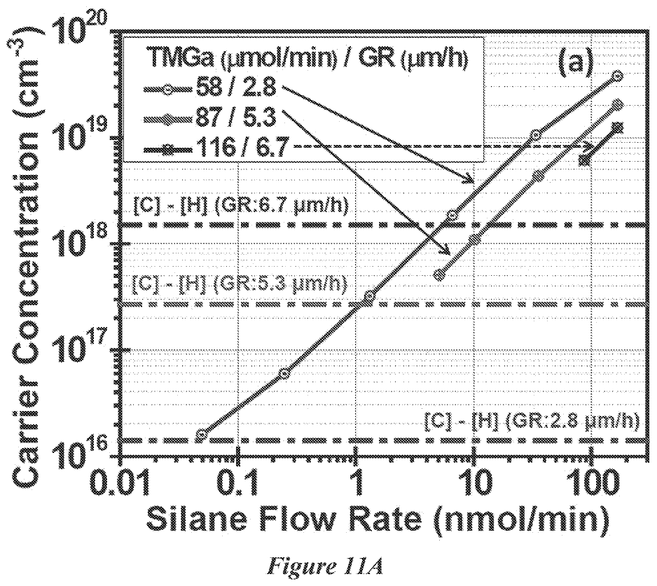

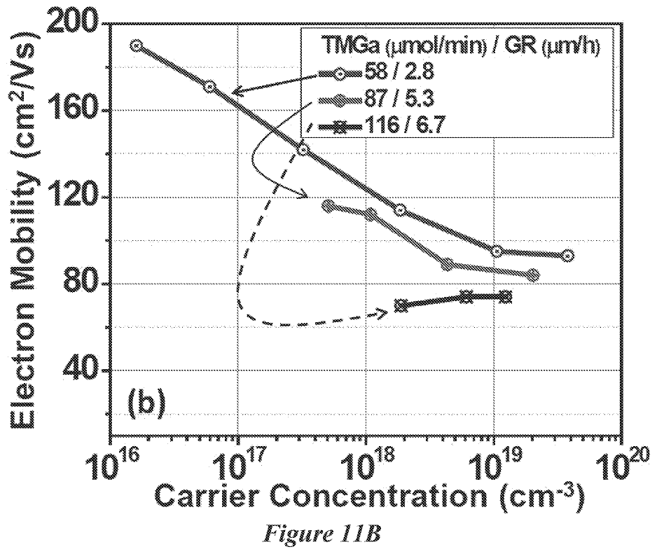

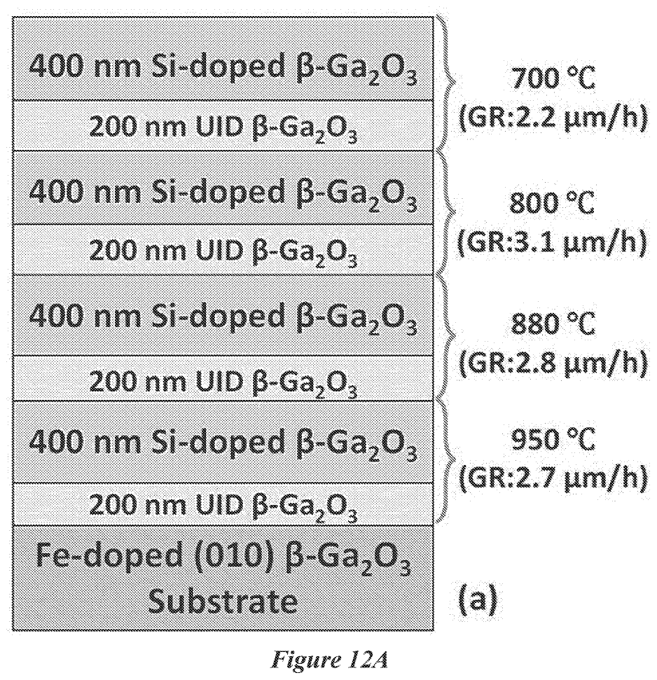

To study the compensation effect from C, a series of samples grown at different growth rates with different silane flow rates were designed for Hall measurements. As shown in FIG. 11A, the carrier concentration and electron mobility of three sets of samples with different growth rates (2.8 μm/h, 5.3 μm/h and 6.7 μm/h) were characterized as a function of the silane flow rate. With the tuning of silane flow rate in a wide range, the measurable range of free carrier concentration differs drastically for the three sets of samples. For the samples grown at relatively low TMGa flow rate (58 μmol/min) or low growth rate (2.8 μm/h), a wide range of carrier concentration from 1.6×10¹⁶ to 3.8×10¹⁹ cm⁻³ was measurable. However, as the growth rate increases, the measurable range of carrier concentration becomes narrower. In the case of fast growth rate condition at 6.7 μm/h, only samples with high doping concentrations are measurable. Samples grown with low silane flow rates show high resistivity. This trend indicates a strong compensation effect in films grown at fast growth rates with high [C]. By comparing the measured carrier concentration and the corresponding [C], [H] concentrations for each set of samples, it was found that the net concentration of [C]−[H] agrees well with the compensation level for each set with different growth rate. As shown in FIG. 11A, the dash-dot lines ([C]−[H]) plotted based on the quantitative SIMS data, agree well with compensation level for each case with different growth rate. The incorporated H forms C—H complexes and therefore passivates the compensation effect from pure C.

Prior theoretical studies based on the density-function theory (DFT) predicted that C on Ga site (CGa) acts as a shallow donor in Ga₂O₃ and C on oxygen site (CO) acts as a compensating acceptor [63]. However, experimental results do not show good agreement with either of these two cases. In previous studies [25], the temperature dependent Hall measurement of the β-Ga₂O₃ epi-film grown with the TMGa flow rate of 58 μmol/min (growth rate of 2.95 μm/h) revealed an extracted charge compensation level of 1.45×10¹⁵ cm⁻³, while the corresponding SIMS data showed [C] and [H] were at ~ mid-10¹⁶ cm⁻³. This shows a strong indication of the passivation effect of H on the C compensation. Recent DFT calculations also show the neutralization of C—H complexes in β-Ga₂O₃ [63]. Therefore, for the MOCVD growth of β-Ga₂O₃, the incorporation of both C and H can reduce the net compensation level to [C]−[H], Particularly, as shown in FIG. 10, with relatively low TMGa flow rate (<58 μmol/min), the [H] is comparable to [C], thus the net compensation level ([C]−[H]) is significantly suppressed, which enables the tunable doping level at low-10¹⁶ cm⁻³. As the TMGa flow rate increases (>58 μmol/min), [C] increases faster as compared to [H], which leads to a strong increase of the net compensation level ([C]−[H]). Thus, the controllable net carrier concentration strongly depends on the growth rate.

The electron mobility as a function of carrier concentration for samples grown with different TMGa flow rates/growth rates is shown in FIG. 11B. With the same TMGa flow rate/growth rate, the general trend shows that the electron mobility decreases as the carrier concentration increases. For the case with fast growth rate at 6.7 μm/h and strong compensation, the electron mobility does not show obvious dependence on the carrier concentration within the measurable range. With the same carrier concentration, the electron mobility decreases as the growth rate increases. This is likely due to the increased scattering mechanism from the high compensation concentration.

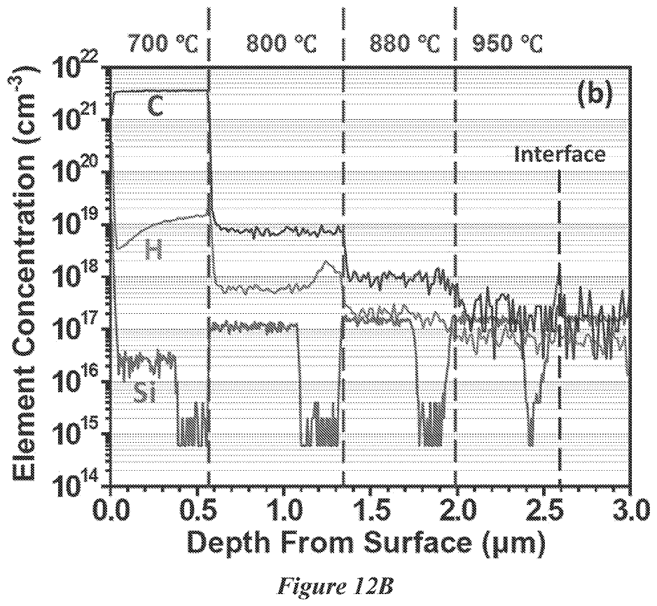

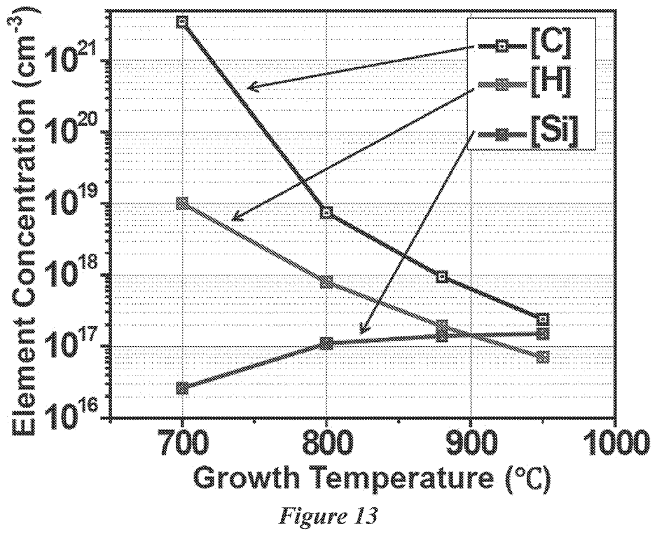

In addition to the growth rate, the growth temperature is expected to affect C incorporation in MOCVD β-Ga₂O₃. In this work, the impurities incorporation as a function of growth temperature were studied with another designed growth stack (stack II), as shown in FIG. 12A. The TMGa molar flow rate and chamber pressure were set at 58 μmol/min and 60 torr, respectively. The silane flow rate was set at 0.416 nmol/min in the Si-doped sub-layers. The growth temperature was varied from 950 °C to 700 °C. The SIMS depth profiles of impurity elements C, H and Si were shown in FIG. 12B. The detection limit for C, H and Si is 1×10¹⁷ cm⁻³, 5×10¹⁶ cm⁻³, and 5×10¹⁵ cm⁻³, respectively. The growth rate of β-Ga₂O₃ under different growth temperature was estimated from the SIMS depth profiles and was listed in FIG. 12A. As shown in FIG. 12B, the C incorporation has a strong dependence on the growth temperature. The [C] increases from ~7×10¹⁶ cm⁻³ to 3.5×10²¹ cm⁻³ as the growth temperature decreases from 950 °C to 700 °C. Within the same growth temperature range, the [H] increases from 7.0×10¹⁶ cm⁻³ to 1.0×10¹⁹ cm⁻³. In contrast, [Si] does not show a strong dependence on the growth temperature. The extracted C, H and Si concentrations as a function of the growth temperature was plotted in FIG. 13. Both [C] and [H] increase as growth temperature decreases, but [C] increases faster as compared to [H]. At relatively high growth temperature, the net compensation ([C]−[H]) can be maintained at relatively low level. The slight decrease of [Si] from 950 °C to 800 °C is mainly due to the slight increase of the corresponding growth rate from 2.7 μm/h to 3.1 μm/h. The lower Si concentration at 700 °C is mainly attributed to the lower Si incorporation efficiency at low temperatures.

In conclusion, the role of C on the compensation effect in the MOCVD β-Ga₂O₃ epitaxy using TMGa as the Ga precursor was systematically investigated. The results revealed that both high TMGa flow rate/growth rate and low growth temperature can lead to higher C incorporation. Typically, [H] in MOCVD β-Ga₂O₃ increases with [C], but with a slower increasing rate. The formation of C—H complexes in MOCVD β-Ga₂O₃ results in the passivation of the compensation effect from pure C. The quantitative SIMS and charge transport characteristics revealed that the net compensation effect is determined to be [C]−[H]. Results from this work indicate that (i) the background C incorporation is highly dependent on the MOCVD growth condition; (ii) the [C] can be widely controlled from below C detection limit (~5×10¹⁶ cm⁻³) to as high as mid-10²¹ cm⁻³, indicating a potential effective approach to control the conductivity of the film; and (iii) intentional incorporation of H in MOCVD β-Ga₂O₃ can potentially suppress the compensation level via the passivation of C. These results can provide valuable guidance and flexibility for future device design and development.

### References

[1] H. H. Tippins, Phys. Rev. 140, A316 (1965).
[2] T. Onuma et al. Appl. Phys. Lett. 103, 041910 (2013).
[3] M. Higashiwaki et al. Appl. Phys. Lett. 100, 013504 (2012).
[4] M. Baldini et al. J. Mater. Sci. 51, 3650 (2016).
[5] K Goto et al. Thin Solid Films 666, 182 (2018).
[6] E. Ahmadi et al. Appl. Phys. Express 10, 041102 (2017).
[7] Y. Zhang et al. APL Mater. 7, 022506 (2019).
[8] S. Rafique et al. Phys. Status Solidi A 215, 1700467 (2018).
[9] A. Kuramata et al. Jpn. J. Appl. Phys. 55, 1202A2 (2016).
[10] K. D. Leedy et al. APL Mater. 6, 101102 (2018).
[11] K. Sasaki et al. Appl. Phys. Express 5, 035502 (2012).
[12] A. Mauze et al. Appl. Phys. Lett. 117, 222102 (2020).
[13] J. H. Leach et al. APL Mater. 7, 022504 (2019).
[14] Y. Zhang et al. J. Vac. Sci. Technol. A 38, 050806 (2020).
[15] A. Bhattacharyya et al. Appl. Phys. Lett. 117, 142102 (2020).
[16] M. Baldini et al. ECS J. Solid State Sci. Technol. 6, Q3040 (2016).
[17] S. Bin Anooz et al. Appl. Phys. Lett. 116, 182106 (2020).
[18] T.-S. Chou et al. AIP Adv. 11, 115323 (2021).
[19] F. Alema et al. AIP Adv. 10, 085002 (2020).
[20] G. Seryogin et al. Appl. Phys. Lett. 117, 262101 (2020).
[21] F. Alema et al. APL Mater. 8, 021110 (2020).
[22] F. Alema et al. APL Mater. 9, 091102 (2021).
[23] Z. Feng et al. Appl. Phys. Lett. 114, 250601 (2019).
[24] Z. Feng et al. Phys. Status Solidi RRL—Rapid Res. Lett. 14, 2000145 (2020).
[25] L. Meng et al. Cryst. Growth Des. 22, 3896 (2022).
[26] A. Bhattacharyya et al. APL Mater. 11, 021110 (2023).
[27] L. Meng et al. J. Vac. Sci. Technol. A 40, 062706 (2022).
[28] A. F. M. A. U. Bhuiyan et al. Appl. Phys. Lett. 115, 120602 (2019).
[29] A. F. M. A. U. Bhuiyan et al. APL Mater. 8, 031104 (2020).
[30] A. F. M. A. U. Bhuiyan et al. J. Mater. Res. 36, 4804 (2021).
[31] A. F. M. A. U. Bhuiyan et al. J. Appl. Phys. 131, 145301 (2022).
[32] A. F. M. Anhar Uddin Bhuiyan et al. Cryst. Growth Des. 20, 6722 (2020),
[33] A. F. M. A. U. Bhuiyan et al. Appl. Phys. Lett. 117, 142107 (2020).
[34] A. F. M. A. Uddin Bhuiyan et al. APL Mater, 11, 041112 (2023).
[35] M.-Y. Tsai et al. J. Vac. Sci. Technol. A 28, 354 (2010).
[36] P. Vogt et al. Appl. Phys. Lett. 108, 072101 (2016).
[37] M. Orita et al. Thin Solid Films 411, 134 (2002).
[38] K. D. Leedy et al. Appl. Phys. Lett. 111, 012103 (2017).
[39] K. Matsuzaki et al. Thin Solid Films 496, 37 (2006).
[40] K. Nomura et al. J. Cryst. Growth 405, 19 (2014).
[41] H. Murakami et al. Appl. Phys. Express 8, 015503 (2014).
[42] Y. Oshima et al. Appl. Phys. Express 8, 055501 (2015).
[43] S. Rafique et al. Appl. Phys. Lett. 112, 052104 (2018).
[44] S. Rafique et al. Appl. Phys. Lett. 108, 182105 (2016).
[45] S. Saha et al. Appl. Phys. Lett. 120, 122106 (2022).
[46] G. Wagner et al. Phys. Status Solidi A 211, 27 (2014).
[47] A. Fiedler et al. J. Appl. Phys. 122, 165701 (2017).
[48] R. Schewski et al. APL Mater. 7, 022515 (2019).
[49] Z. Feng et al. Phys. Status Solidi RRL—Rapid Res. Lett. 14, 2000145 (2020).
[50] Z. Hu et al. IEEE Electron Device Lett. 39, 869 (2018).
[51] W. Li et al. IEEE Electron Device Lett. 41, 107 (2020).
[52] J. Yang et al. ECS J. Solid State Sci. Technol. 7, Q92 (2018).
[53] S. Kumar et al. Appl. Phys. Express 15, 054001 (2022).
[54] P. Dong et al. IEEE Electron Device Lett. 43, 765 (2022).
[55] J.-S. Li et al. Appl. Phys. Lett. 121, 042105 (2022).
[56] J. Zhang et al. Nat. Commun. 13, 3900 (2022).
[57] A. G. Thompson, Mater. Lett. 30, 255 (1997).
[58] C. A. Larsen et al. J. Cryst. Growth 102, 103 (1990).
[59] P. W. Lee et al. J. Cryst. Growth 85, 165 (1987).
[60] M. Pristovsek et al. J. Cryst. Growth 262, 78 (2004).
[61] J. L. Lyons et al. Appl. Phys. Lett. 97, 152108 (2010).
[62] N. Sawada et al. Appl. Phys. Express 11, 041001 (2018).
[63] S. Mu et al. Phys. Rev. B 105, 155201 (2022).

Other advantages which are obvious and which are inherent to the invention will be evident to one skilled in the art. It will be understood that certain features and sub-combinations are of utility and may be employed without reference to other features and sub-combinations. This is contemplated by and is within the scope of the claims. Since many possible embodiments may be made of the invention without departing from the scope thereof, it is to be understood that all matter herein set forth or shown in the accompanying drawings is to be interpreted as illustrative and not in a limiting sense.

The methods of the appended claims are not limited in scope by the specific methods described herein, which are intended as illustrations of a few aspects of the claims and any methods that are functionally equivalent are intended to fall within the scope of the claims. Various modifications of the methods in addition to those shown and described herein are intended to fall within the scope of the appended claims. Further, while only certain representative method steps disclosed herein are specifically described, other combinations of the method steps also are intended to fall within the scope of the appended claims, even if not specifically recited. Thus, a combination of steps, elements, components, or constituents may be explicitly mentioned herein or less, however, other combinations of steps, elements, components, and constituents are included, even though not explicitly stated.

1. A composition comprising β-Ga₂O₃ doped with carbon, wherein the composition is semi-insulating or insulating.

2. The composition of claim 1, wherein the composition is further doped with hydrogen and/or silicon, and the concentration of carbon in the composition is greater than the concentration of hydrogen and/or silicon.

3. The composition of claim 1, wherein the carbon is present in the composition at a concentration of from 1×10¹⁶ per cubic centimeter to 1×10²² cm⁻³.

4. The composition of claim 2, wherein the composition is further doped with hydrogen and the hydrogen is present in the composition at a concentration of from 1×10¹⁶ per cubic centimeter to 1×10²² cm⁻³.

5. The composition of claim 2, wherein the composition is further doped with silicon and the silicon is present in the composition at a concentration of from 1×10¹⁵ per cubic centimeter to 1×10²² cm⁻³.

6. (canceled)

7. The composition of claim 1, wherein the composition has a carrier concentration of from 1×10¹⁵ per cubic centimeter to 1×10²² cm⁻³.

8. The composition of claim 2, wherein the composition consists essentially of β-Ga₂O₃, carbon, hydrogen, and silicon.

9. A method of making the composition of claim 1, the method comprising contacting a first precursor and a second precursor at a first temperature, wherein the first precursor comprises carbon and gallium, the second precursor comprises oxygen, and the first precursor and the second precursor each independently comprises a fluid, to thereby react the first precursor and the second precursor to form the composition comprising β-Ga₂O₃ doped with carbon.

10. The method of claim 9, wherein the method comprises metal organic chemical vapor deposition (MOCVD), molecular-beam epitaxy (MBE), hydride vapor phase epitaxy (HVPE), pulsed laser deposition (PLD), low pressure chemical vapor deposition (LPCVD), mist-CVD, or a combination thereof.

11. (canceled)

12. (canceled)

13. The method of claim 9, wherein the first precursor further comprises hydrogen, and wherein the composition optionally further comprises hydrogen.

14. The method of claim 9, wherein:
the first precursor comprises trimethylgallium (TMGa), triethylgallium (TEGa), Ga(DPM)₃ (DPM=dipivaloylmethanate), or a combination thereof;
the second precursor comprises O₂;
or a combination thereof.

15. (canceled)

16. The method of claim 9, wherein the first precursor is provided at a flow rate of from 1 to 250 μmole/minute.

17. (canceled)

18. The method of claim 9, wherein the first temperature is from 550 °C to 1200 °C.

19. The method of claim 9, wherein the method further comprises controlling the flow rate of the first precursor, the temperature, or a combination thereof to thereby control the concentration of carbon in the resulting composition.

20. The method of claim 9, wherein the method produces the composition at a growth rate of from 0.2 to 20 μm/hour.

21. (canceled)

22. The method of claim 9, wherein the method further comprises introducing a third precursor comprising an additional dopant, such that the composition further comprises the additional dopant.

23. The method of claim 22, wherein the third precursor is provided as a fluid.

24. The method of claim 22, wherein the third precursor comprises silane (SiH₄), germane (GeH₄), disilane(Si₂H₆), bis(cyclopentadienyl)magnesium (Cp₂Mg), bis(methylcyclopentadienyl)magnesium ((MeCp)₂Mg), or a combination thereof.

25.-28. (canceled)

29. A device comprising the composition of claim 1, wherein the device comprises an optical device, an electronic device, an optoelectronic device, or a combination thereof.

30. The device of claim 29, wherein the device comprises a MESFET device, a MODFET device, a MOSFET device, a Current Aperture Vertical Electron Transistor (CAVET) device, a vertical power device, a diode, or a combination thereof.

31.-34. (canceled)
